(19) United States
(12) Patent Application Publication
(10) Pub. No.: US 2023/0144896 A1
(43) Pub. Date: May 11, 2023

(54) SUBSTRATE TREATING APPARATUS AND SEMICONDUCTOR MANUFACTURING EQUIPMENT INCLUDING THE SAME

(71) Applicant: SEMES CO., LTD., Chungcheongnam-do (KR)

(72) Inventors: Young Je UM, Busan (KR); Wan Jae PARK, Gyeonggi-do (KR); Dong Hun KIM, Seoul (KR); Seong Gil LEE, Gyeonggi-do (KR); Dong Sub OH, Busan (KR); Myoung Sub NOH, Gyeonggi-do (KR); Min Sung HAN, Gyeonggi-do (KR); Jae Hoo LEE, Gyeonggi-do (KR)

(21) Appl. No.: 17/879,780

(22) Filed: Aug. 3, 2022

(30) Foreign Application Priority Data
Nov. 9, 2021 (KR) 10-2021-0152771

(51) Int. Cl. H01L 21/677; H01L 21/67; C23C 16/44

(52) U.S. Cl. CPC H01L 21/67766; H01L 21/67103; C23C 16/4408; H01L 21/67034

(57) ABSTRACT

A substrate treating apparatus configuring an individual LL for each PM and a semiconductor manufacturing facility including the same are provided. The semiconductor manufacturing facility comprises an index module including a first transfer robot and for carrying out and transferring a substrate mounted on a container using the first transfer robot, a transfer module including a second transfer robot and for relaying the substrate transferred by the index module using the second transfer robot, a buffer chamber for heating the substrate relayed by the transfer module, and a process chamber for treating the substrate heated by the buffer chamber, wherein the buffer chamber heats the substrate while the substrate waits before being loaded into the process chamber.

This application claims the benefit of Korean Patent Application No. 10-2021-0152771, filed on Nov. 9, 2021, in the Korean Intellectual Property Office, the disclosure of which is incorporated herein by reference in its entirety.

### BACKGROUND

### 1. Field

The present invention relates to a substrate treating apparatus for treating a substrate and a semiconductor manufacturing facility including the same. More particularly, it relates to a substrate treating apparatus for cleaning a substrate and a semiconductor manufacturing facility including the same.

### 2. Description of the Related Art

The semiconductor manufacturing process may be continuously performed in a semiconductor manufacturing facility, and may be divided into a pre-process and a post-process. The semiconductor manufacturing facility may be installed in a space defined as a FAB to manufacture a semiconductor.

The pre-process refers to a process of forming a circuit pattern on a wafer to complete a chip. The pre-process may include a deposition process that forms a thin film on the wafer, a photo lithography process that transfers photo resist onto the thin film using a photo mask, an etching process that selectively removes unnecessary parts using chemical substances or reactive gases to from a desired circuit pattern on the wafer, an ashing process that removes the photoresist remaining after etching, and an ion implantation process that implants ions into a part connected to the circuit pattern to have characteristics of an electronic device, a cleaning process that removes contaminants from the wafer, and the like.

The post-process refers to the process of evaluating the performance of the product finished through the pre-process. The post-process may include the primary inspection process for selecting good and bad products by inspecting the operation of each chip on the wafer, the package process for cutting and separating each chip to form the shape of the product through dicing, die bonding, wire bonding, molding, and marking, and the final inspection process for finally inspecting product characteristics and reliability through electrical characteristic inspection, and burn-in inspection.

### SUMMARY

In the case of a cleaning process of removing contaminants (e.g., particles) from a wafer, the wafer may be dry cleaned using radicals in a dry clean facility.

In this case, before putting the target wafer into the dry clean facility, the temperature of the target wafer should be adjusted to an appropriate temperature, and to this end, the target wafer should be heated for a predetermined time.

However, since the conventional equipment has to respond to a large number of PMs (process modules) with a small number of LL (Load Lock), it takes a lot of time to put a target wafer into a dry clean facility.

A technical object of the present invention is to provide a substrate treating apparatus for configuring individual LLs for each PM and a semiconductor manufacturing facility including the same.

The objects of the present invention are not limited to the objects mentioned above, and other objects not mentioned will be clearly understood by those skilled in the art from the following description.

One aspect of the semiconductor manufacturing facility of the present invention for achieving the above technical object comprises an index module including a first transfer robot and for carrying out and transferring a substrate mounted on a container using the first transfer robot; a transfer module including a second transfer robot and for relaying the substrate transferred by the index module using the second transfer robot; a buffer chamber for heating the substrate relayed by the transfer module; and a process chamber for treating the substrate heated by the buffer chamber, wherein the buffer chamber heats the substrate while the substrate waits before being loaded into the process chamber.

Wherein the buffer chamber heats the substrate while the substrate treated by the process chamber waits before being carried out.

Wherein the buffer chamber is provided separately in each process chamber in response to the process chamber being plural, and an inside of the transfer module is an atmospheric pressure environment.

Wherein the buffer chamber is coupled to a front surface of the process chamber, into which the substrate is loaded.

Wherein the buffer chamber provides a purge gas to the substrate while the substrate is heated.

Wherein the purge gas is a gas having a high temperature higher than room temperature.

Wherein the second transfer robot transfers the substrate heated by the buffer chamber to the process chamber, and an inside of the transfer module is a vacuum environment.

Wherein a heating wire is installed in an end effector of the second transfer robot.

Wherein the buffer chamber is installed inside the transfer module.

Wherein the buffer chamber is installed in a contact surface with the index module, is further installed in a surface facing the contact surface, or is installed in a section between two different process chambers in response to the process chamber being plural.

Wherein the buffer chamber heats the substrate above a reference temperature, and the reference temperature is a temperature, at which the substrate can be immediately treated in the process chamber.

Wherein the process chamber uses radicals to clean the substrate.

Another aspect of the semiconductor manufacturing facility of the present invention for achieving the above technical object comprises an index module including a first transfer robot and for carrying out and transferring a substrate mounted on a container using the first transfer robot; a transfer module including a second transfer robot and for relaying the substrate transferred by the index module using the second transfer robot; a buffer chamber for heating the substrate relayed by the transfer module; and a process chamber for treating the substrate heated by the buffer chamber, wherein the buffer chamber heats the substrate while the substrate waits before being loaded into the process chamber, and heats the substrate while the substrate treated by the process chamber waits before being carried out, wherein, in response to the process chamber being plural, the buffer chamber is provided separately in each process chamber, and is coupled to a front surface of the process chamber, into which the substrate is loaded, wherein the buffer chamber provides a purge gas to the substrate while the substrate is heated, and the purge gas is a gas having a high temperature higher than room temperature.

One aspect of the substrate treating apparatus of the present invention for achieving the above technical object comprises a process chamber for treating a substrate; and a buffer chamber for providing a space, in which the substrate waits, wherein the substrate waits in the buffer chamber before being loaded into the process chamber, and waits in the buffer chamber before being carried out after being treated by the process chamber, wherein the buffer chamber heats the substrate while the substrate waits.

The details of other embodiments are included in the detailed description and drawings.

### BRIEF DESCRIPTION OF THE DRAWINGS

These and/or other aspects will become apparent and more readily appreciated from the following description of the embodiments, taken in conjunction with the accompanying drawings in which:

FIG. 1 is a diagram schematically illustrating an internal structure of a semiconductor manufacturing facility according to a first embodiment of the present invention;

FIG. 2 is a first exemplary diagram schematically illustrating an internal structure of a buffer chamber constituting a semiconductor manufacturing facility according to various embodiments of the present invention;

FIG. 3 is a second exemplary diagram schematically illustrating an internal structure of a buffer chamber constituting a semiconductor manufacturing facility according to various embodiments of the present invention;

FIG. 4 is a first exemplary view for describing a method of moving a substrate between a buffer chamber and a process chamber constituting a semiconductor manufacturing facility according to various embodiments of the present disclosure;

FIG. 5 is a second exemplary view for describing a method of moving a substrate between a buffer chamber and a process chamber constituting a semiconductor manufacturing facility according to various embodiments of the present disclosure;

FIG. 6 is a diagram schematically illustrating an internal structure of a semiconductor manufacturing facility according to a second embodiment of the present invention;

FIG. 7 is a diagram schematically illustrating an internal structure of a semiconductor manufacturing facility according to a third embodiment of the present invention;

FIG. 8 is a diagram schematically illustrating an internal structure of a semiconductor manufacturing facility according to a fourth embodiment of the present invention;

FIG. 9 is a diagram schematically illustrating an internal structure of a semiconductor manufacturing facility according to a fifth embodiment of the present invention;

FIG. 10 is a diagram schematically illustrating an internal structure of a semiconductor manufacturing facility according to a sixth embodiment of the present invention; and

FIG. 11 is a diagram schematically illustrating an internal structure of a semiconductor manufacturing facility according to a seventh embodiment of the present invention.

### DETAILED DESCRIPTION

Hereinafter, preferred embodiments of the present disclosure will be described in detail with reference to the accompanying drawings. Advantages and features of the present disclosure and methods of achieving them will become apparent with reference to the embodiments described below in detail in conjunction with the accompanying drawings. However, the present disclosure is not limited to the embodiments described below, but may be implemented in various different forms, and these embodiments are provided only for making the description of the present disclosure complete and fully informing those skilled in the art to which the present disclosure pertains on the scope of the present disclosure, and the present disclosure is only defined by the scope of the claims. Like reference numerals refer to like elements throughout.

When an element or layer is referred as being located “on” another element or layer, it includes not only being located directly on the other element or layer, but also with intervening other layers or elements. On the other hand, when an element is referred as being “directly on” or “immediately on,” it indicates that no intervening element or layer is interposed.

Spatially relative terms “below,” “beneath,” “lower,” “above,” and “upper” can be used to easily describe a correlation between an element or components and other elements or components. The spatially relative terms should be understood as terms including different orientations of the device during use or operation in addition to the orientation shown in the drawings. For example, when an element shown in the figures is turned over, an element described as “below” or “beneath” another element may be placed “above” the other element. Accordingly, the exemplary term “below” may include both directions below and above. The device may also be oriented in other orientations, and thus spatially relative terms may be interpreted according to orientation.

Although first, second, etc. are used to describe various elements, components, and/or sections, it should be understood that these elements, components, and/or sections are not limited by these terms. These terms are only used to distinguish one element, component, or section from another element, component, or section. Accordingly, the first element, the first component, or the first section mentioned below may be the second element, the second component, or the second section within the technical spirit of the present disclosure.

The terminology used herein is for the purpose of describing the embodiments and is not intended to limit the present disclosure. In the present disclosure, the singular also includes the plural, unless specifically stated otherwise in the phrase. As used herein, “comprises” and/or “comprising” refers to that components, steps, operations and/or elements mentioned does not exclude the presence or addition of one or more other components, steps, operations and/or elements.

Unless otherwise defined, all terms (including technical and scientific terms) used herein may be used with the meaning commonly understood by those of ordinary skill in the art to which the present invention belongs. In addition, terms defined in a commonly used dictionary are not to be interpreted ideally or excessively unless clearly defined in particular.

Hereinafter, embodiments of the present disclosure will be described in detail with reference to the accompanying drawings, and in the description with reference to the accompanying drawings, the same or corresponding components are given the same reference numbers, regardless of reference numerals in drawings, and an overlapped description therewith will be omitted.

The present invention relates to a substrate treating apparatus configuring an individual LL (Load Lock) for each PM (Process Module) and a semiconductor manufacturing facility including the same. Hereinafter, the present invention will be described in detail with reference to drawings and the like.

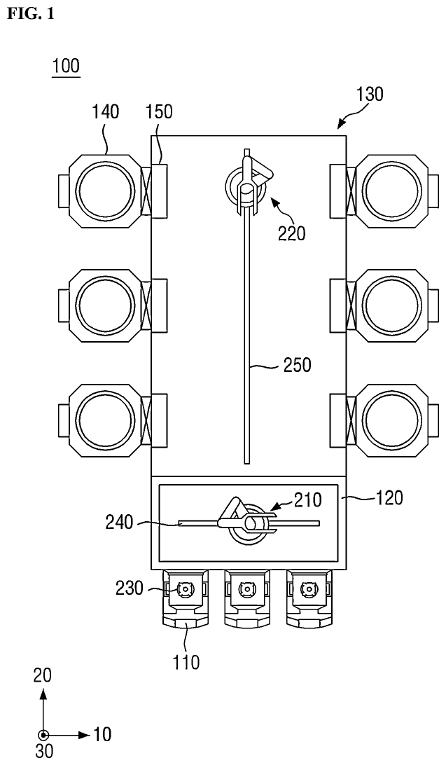

FIG. 1 is a diagram schematically illustrating an internal structure of a semiconductor manufacturing facility according to a first embodiment of the present invention.

Referring to FIG. 1, a semiconductor manufacturing facility 100 may include a load port module 110, an index module 120, a transfer module 130, a process chamber 140 and a buffer chamber 150.

The semiconductor manufacturing facility 100 is a system for treating a substrate (e.g., a wafer), and undergoes various processes such as a bake process, an etching process, and a cleaning process to treat a plurality of substrates. The semiconductor manufacturing facility 100 may be provided as a multi-chamber type semiconductor manufacturing facility, including the transfer robots 210 and 220 that treats the transfer of substrates and a plurality of process chambers 140 that are substrate treating modules provided around them.

The semiconductor manufacturing facility 100 may be configured to share the index module 120 and the transfer module 130 that are closely disposed with each other. That is, with the index module 120 and the transfer module 130 interposed therebetween, the plurality of load port modules 110 may be disposed on one side of the index module 120, and the plurality of process chambers 140 may be disposed on both sides of the transfer module 130. When the semiconductor manufacturing facility 100 is configured in this way, it becomes possible to operate the plurality of load port modules 110 and the plurality of process chambers 140 even with one substrate handling apparatus 210 and 220, respectively, and accordingly, it is possible to obtain the effect of securing the main space and improving space efficiency.

The load port module (LPM) 110 provides a seating surface for the container 230 (e.g., a Front Opening Unified Pod (FOUP)), on which a plurality of substrates are mounted. The load port module 110 may serve to open and close the door of the container 230 so that the first transfer robot 210 can transfer the substrate mounted on the container 230.

A plurality of load port modules 110 may be installed adjacent to the outside of the index module 120. In this case, the container 230 seated on each load port module 110 may mount the same object, but it is also possible to mount different objects. For example, some containers 230 among the plurality of containers 230 may mount a substrate, and some containers 230 may mount a consumable component (e.g., a focus ring).

The index module 120 is an interface module provided to transfer the substrate between the container 230 on the load port module 110 and the second transfer robot 220 of the transfer module 130. The index module 120 may be provided in the form of a Front End Module (FEM), such as an Equipment Front End Module (EFEM), and an SFEM.

The index module 120 may be configured to include the first transfer robot 210 therein to serve as an interface module. The first transfer robot 210 may serve to carry out the untreated substrate mounted on the container 230 and provide it to the process chamber 140 through the second transfer robot 220 of the transfer module 130 or may serve to load the treated substrate into the container 230 when the treated substrate is provided from the process chamber 140. The first transfer robot 210 may operate in an atmospheric pressure environment, and may be provided as, for example, an ATM (Atmosphere Transfer Module) robot.

The first transfer robot 210 may move along the first rail 240 installed in the index module 120 to manage all of the containers 230 seated on the load port module 110. The first rail 240 may be installed in a direction parallel to the arrangement direction of the plurality of load port modules 110 (i.e., the first direction 10).

A plurality of first transfer robots 210 may be installed on one first rail 240. Alternatively, a plurality of first rails 240 may be installed, and one first transfer robot 210 may be installed on each first rail 240. Alternatively, a plurality of first rails 240 may be installed, and a plurality of first transfer robots 210 may be installed on at least one first rail 240. However, the present embodiment is not limited thereto. Each of the first transfer robot 210 and the first rail 240 may be provided in the index module 120 one by one.

When a plurality of first transfer robots 210 are installed, some of the first transfer robots 210 may not operate normally. In this embodiment, in this case, it is also possible to control some other first transfer robots 210 that normally operate to take over the role instead. That is, in the present invention, by installing a plurality of first transfer robots 210, it is possible to obtain an effect of preparing for the case where at least one first transfer robot 210 does not operate normally.

Meanwhile, although not shown in FIG. 1, the index module 120 may further include a buffer unit and an alignment unit. Here, the buffer unit serves to temporarily store untreated substrates carried out from the container 230 or treated substrates to be loaded into the container 230. The buffer unit may serve to remove particles or fume by heating the substrate while temporarily storing the substrate.

Meanwhile, when the first transfer robot 210 transfers the substrate, the alignment unit aligns the substrate seated on the end effector of the first transfer robot 210.

The transfer module 130 transfers a substrate between the load port module 110 and the process chamber 140 in conjunction with the index module 120. The transfer module 130 may include a second transfer robot 220 and a second rail 250 for this purpose.

The second transfer robot 220 may transfer an untreated substrate to the process chamber 140, or transfer a pre-treated substrate to the load port module 110 through the first transfer robot 210. Each side of the transfer module 130 may be connected to the index module 120 and the plurality of process chambers 140 for this purpose.

Meanwhile, the second transfer robot 220 operates in a vacuum environment and may be freely rotated. However, the present embodiment is not limited thereto. Like the first transfer robot 210, the second transfer robot 220 may operate in an atmospheric pressure environment.

A plurality of second transfer robots 220 may be installed on one second rail 250. Alternatively, a plurality of second rails 250 may be installed, and one second transfer robot 220 may be installed on each second rail 250. Alternatively, a plurality of second rails 250 may be installed, and a plurality of second transfer robots 220 may be installed on at least one second rail 250. However, the present embodiment is not limited thereto. Each of the second transfer robot 220 and the second rail 250 may be provided in the transfer module 130 one by one.

The process chamber 140 treats a substrate. The process chamber 140 may be provided as a cleaning chamber for treating a substrate using a cleaning process. The process chamber 140 may be provided as, for example, dry clean equipment for dry cleaning the substrate using radicals. However, the present embodiment is not limited thereto. The process chamber 140 may be provided as an etching chamber for treating a substrate using an etching process, a bake chamber for treating a substrate using a heat treatment process, or the like.

A plurality of process chambers 140 may be disposed around the transfer module 130. In this case, each process chamber 140 may receive a substrate from the transfer module 130 to treat the substrate, and provide the treated substrate to the transfer module 130.

The process chamber 140 may be formed in a cylindrical shape. The process chamber 140 may have a surface made of alumite, on which an anodic oxide film is formed, and the inside thereof may be hermetically configured. Meanwhile, the process chamber 140 may be formed in a polygonal shape other than a cylindrical shape.

The buffer chamber 150 temporarily waits untreated substrates loaded into the process chamber 140, pre-treated substrates carried out from the process chamber 140, and the like. The buffer chamber 150 may be provided as, for example, a load lock chamber.

The buffer chamber 150 may be installed on a front surface of the process chamber 140. In this case, the number of buffer chambers 150 may be the same as that of the process chambers 140. That is, the buffer chamber 150 may be provided as a dedicated chamber. In the present invention, by configuring the individual buffer chambers 150 for each process chamber 140 as described above, it is possible to obtain an effect of shortening the time required to load the substrate into the corresponding process chamber 140. In the following description, the buffer chamber 150 disposed on a front surface of the process chamber 140 and the process chamber 140 are grouped together to be defined as a substrate treating apparatus.

The buffer chamber 150 may serve to heat the substrate before it is loaded into the process chamber 140. Hereinafter, this will be described.

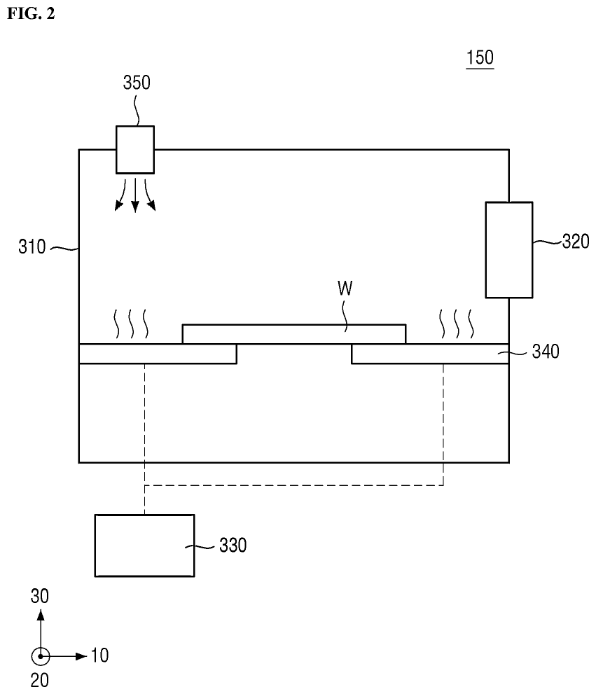

FIG. 2 is a first exemplary diagram schematically illustrating an internal structure of a buffer chamber constituting a semiconductor manufacturing facility according to various embodiments of the present disclosure.

According to FIG. 2, the buffer chamber 150 may include a housing 310, an opening/closing door 320, a power supply unit 330, a heating plate 340, and a purge gas supply unit 350.

The opening/closing door 320 may be installed on the side wall of the housing 310 and may expose the inside of the housing 310 to the outside according to the opening and closing. When the inside of the housing 310 is exposed to the outside according to the operation of the opening/closing door 320, the second transfer robot 220 may load untreated substrates into the buffer chamber 150 or carry out pre-treated substrates from the buffer chamber 150.

The power supply unit 330 supplies power to the heating plate 340. When power is supplied by the power supply unit 330, the heating plate 340 may heat the substrate W using the power.

The heating plate 340 is to heat the substrate W. The heating plate 340 may include a heating element therein, and may heat the substrate W by operating the heating element with power supplied by the power supply unit 330.

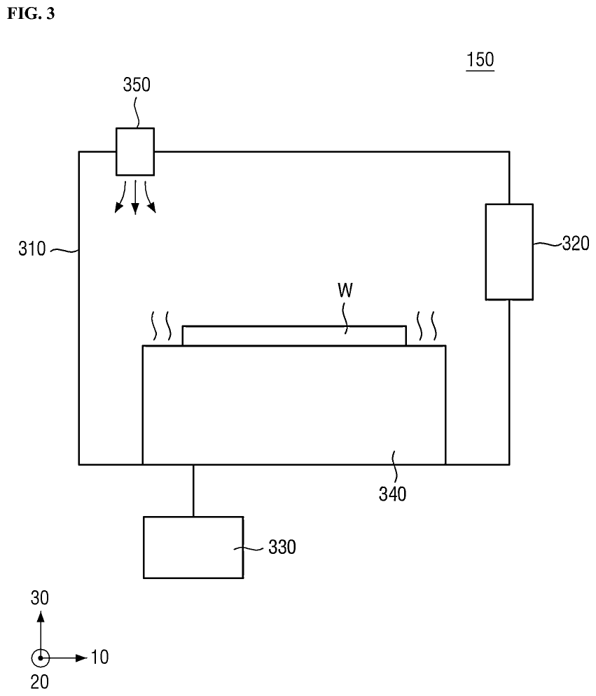

The heating plate 340 may support the substrate W at both sides of the substrate W in order to heat the substrate W. That is, the heating plate 340 may heat the edge region of the substrate W. However, the present embodiment is not limited thereto. The heating plate 340 may also heat the entire region of the substrate W. In this case, the heating plate 340 may be provided as a flat plate that provides a seating surface to the substrate W as shown in FIG. 3.

When the heating plate 340 is provided as the flat plate of FIG. 3, in order to effectively heat the entire surface of the substrate W, the area of the heating plate 340 may be greater than the area of the substrate W or may be equal to the area of the substrate W. Meanwhile, the area of the heating plate 340 may be smaller than the area of the substrate W, and in this case, the heating plate 340 may heat the center region of the substrate W (i.e., a partial region of the substrate W). FIG. 3 is a second exemplary diagram schematically illustrating an internal structure of a buffer chamber constituting a semiconductor manufacturing facility according to various embodiments of the present invention.

It will be described again with reference to FIG. 2.

The purge gas supply unit 350 supplies a purge gas to the inside of the housing 310. The purge gas supply unit 350 may be installed on the upper portion of the housing 310, but may also be installed on the sidewall of the housing 310.

The purge gas supply unit 350 may supply a purge gas to the inside of the housing 310 to remove particles remaining on the substrate W. The purge gas may be, for example, N₂ gas or Ar gas. In this case, the purge gas supply unit 350 may supply hot purge gas to increase the internal temperature of the housing 310 and further improve particle removal efficiency.

When the purge gas supply unit 350 supplies a high-temperature purge gas, the purge gas may be a gas at room temperature (e.g., 15° C.) or higher. Preferably, the purge gas may be a gas of 50° C. or higher. Alternatively, the purge gas may be a gas of 150° C. or higher.

When the buffer chamber 150 is disposed on a front surface of the process chamber 140, the substrate W may be heated in the buffer chamber 150 and then move to the process chamber 140. In this case, the substrate W may move from the buffer chamber 150 to the process chamber 140 through the door 410 provided between the buffer chamber 150 and the process chamber 140.

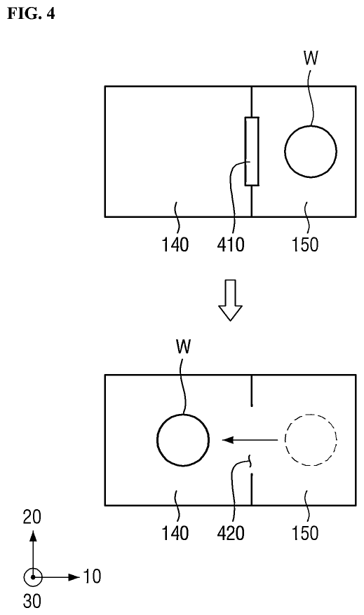

FIG. 4 is a first exemplary diagram illustrating a method of moving a substrate between a buffer chamber and a process chamber constituting a semiconductor manufacturing facility according to various embodiments of the present invention.

When the substrate W is heated to a predetermined temperature in the buffer chamber 150, the door 410 may be opened to allow the substrate W to move from the buffer chamber 150 to the process chamber 140. Then, the substrate W may move from the inside of the buffer chamber 150 into the process chamber 140 through the open section 420 between the buffer chamber 150 and the process chamber 140.

In this case, the substrate W may move from the buffer chamber 150 to the process chamber 140 by a transfer device provided in the buffer chamber 150. In this case, an effect, in which the inside of the buffer chamber 150 and the inside of the process chamber 140 each maintain a vacuum environment, can be obtained. In the above, the transfer device may be a robot arm, but in the present embodiment, any device may be used as long as it can transfer the substrate W.

The substrate W may be moved from the buffer chamber 150 to the process chamber 140 by the second transfer robot 220 of the transfer module 130. In this case, in order to maintain a vacuum environment inside the buffer chamber 150 and the inside of the process chamber 140, respectively, the inside of the transfer module 130 is created as a vacuum environment.

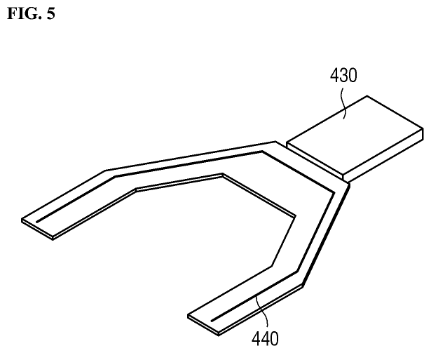

On the other hand, when the device for moving the substrate W from the buffer chamber 150 to the process chamber 140 is a robot arm, as shown in FIG. 5, a heating wire 440 may be formed on the surface of the end effector 430 of the robot arm. Then, even while the robot arm transfers the substrate W, it becomes possible for the substrate W to maintain a certain temperature or more. FIG. 5 is a second exemplary diagram for describing a method of moving a substrate between a buffer chamber and a process chamber constituting a semiconductor manufacturing facility according to various embodiments of the present invention.

It will be described again with reference to FIG. 1.

As described above, the second transfer robot 220 may operate in a vacuum environment or may operate in an atmospheric pressure environment. When the second transfer robot 220 operates in a vacuum environment, the inside of the transfer module 130 creates a vacuum environment, and when the second transfer robot 220 operates in an atmospheric pressure environment, the inside of the transfer module 130 creates an atmospheric pressure environment.

The inside of the process chamber 140 is created as a vacuum environment for treating the substrate W, and the inside of the buffer chamber 150 is created as a vacuum environment for waiting before or after the treating of the substrate W. Accordingly, when the inside of the transfer module 130 creates an atmospheric pressure environment, the buffer chamber 150 may be installed on a front surface of each process chamber 140. In this case, the number of buffer chambers 150 is the same as the number of the process chambers 140.

On the other hand, when the inside of the transfer module 130 creates a vacuum environment, the buffer chamber 150 may not be installed on a front surface of each process chamber 140. That is, the buffer chamber 150 may be provided as a common chamber, and a smaller number of the buffer chambers 150 than the process chamber 140 may be provided.

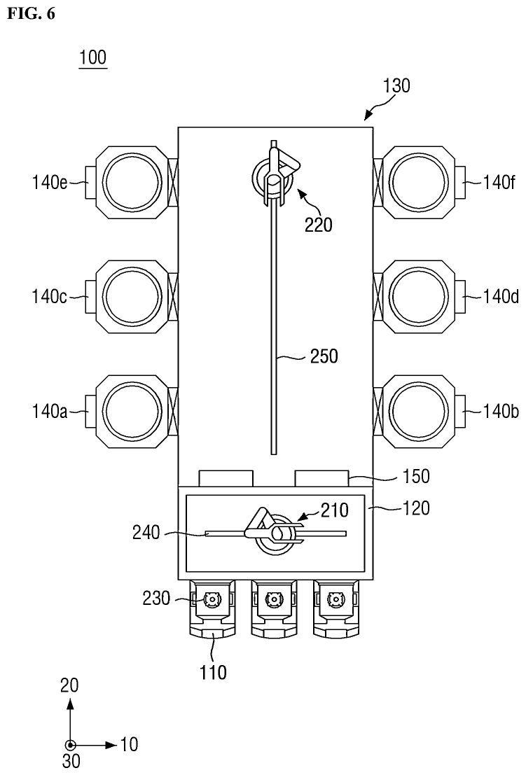

In this case, the buffer chamber 150 may be installed on the inner wall of the transfer module 130 adjacent to the index module 120. FIG. 6 is a diagram schematically illustrating an internal structure of a semiconductor manufacturing facility according to a second embodiment of the present invention.

However, when the buffer chamber 150 is installed as shown in FIG. 6, after the substrate W is heated in the buffer chamber 150 to a predetermined temperature, since the moving distance to the first process chamber 140a and the second process chamber 140b is short, the substrate W may be instantly treated in the first process chamber 140a and the second process chamber 140b without heating the substrate again.

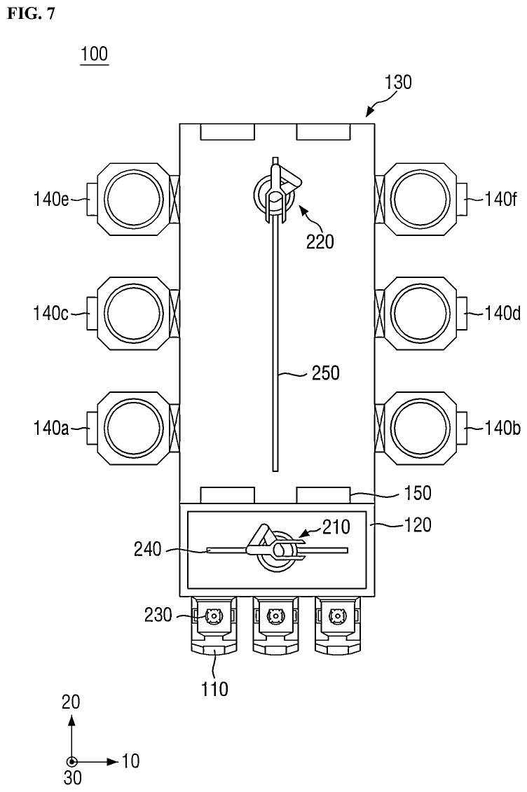

On the other hand, in the case of the fifth process chamber 140e and the sixth process chamber 140f, after the substrate W is heated in the buffer chamber 150, since the moving distance is long, the substrate may need to be heated again in the fifth process chamber 140e and the sixth process chamber 140f Therefore, in this embodiment, taking this case into consideration, the buffer chamber 150 may be additionally installed on the inner wall of the transfer module 130 that is not adjacent to the index module 120 and the process chamber 140 as shown in FIG. 7. FIG. 7 is a diagram schematically illustrating an internal structure of the semiconductor manufacturing facility according to a third embodiment of the present invention.

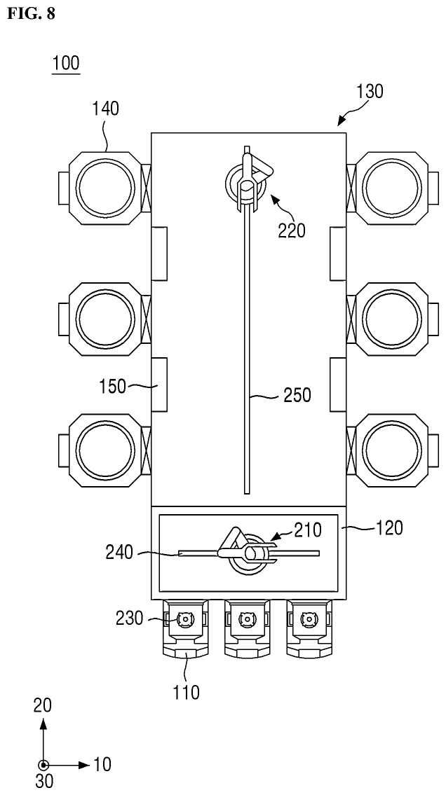

Alternatively, as shown in FIG. 8, the buffer chamber 150 may be provided in a region between two different process chambers 140 among the inner walls of the transfer module 130. FIG. 8 is a diagram schematically illustrating an internal structure of a semiconductor manufacturing facility according to a fourth embodiment of the present invention.

Meanwhile, even when the inside of the transfer module 130 creates a vacuum environment, the buffer chamber 150 may be installed on a front surface of each process chamber 140. That is, even when the inside of the transfer module 130 is created as a vacuum environment, the number of buffer chambers 150 may be the same as the number of the process chambers 140.

Meanwhile, when the buffer chamber 150 is installed in the structure shown in FIG. 6, considering the time taken to move from the buffer chamber 150 to the fifth process chamber 140e and the sixth process chamber 140f and how much the temperature of the substrate W is cooled during the time, it is also possible to heat the substrate W to a temperature higher than the reference temperature by a predetermined temperature in the buffer chamber 150. In the above, the reference temperature refers to a lower limit of a temperature that does not need to be heated again when treating the substrate W in the process chamber 140, and the predetermined temperature refers to a temperature cooled during the moving time.

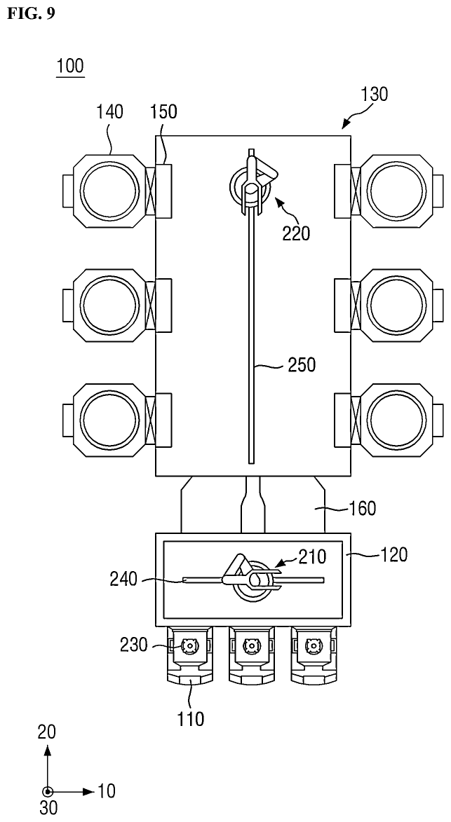

Meanwhile, as shown in FIG. 9, a separate load lock chamber 160 may be provided between the index module 120 and the transfer module 130. As described above, the inside of the index module 120 may be created as an atmospheric pressure environment, and the inside of the transfer module 130 may be created as a vacuum environment. In this case, a load lock chamber 160 that relays the substrate W between the index module 120 and the transfer module 130 may be provided so that each environment can be maintained inside the index module 120 and inside the transfer module 130.

In addition, when the transfer of the substrate W between the first transfer robot 210 of the index module 120 and the second transfer robot 220 of the transfer module 130 is delayed, the load lock chamber 160 may serve as a buffer that temporarily waits the substrate W. The load lock chamber 160 may include a buffer stage therein for this purpose. FIG. 9 is a diagram schematically illustrating an internal structure of a semiconductor manufacturing facility according to a fifth embodiment of the present invention.

A plurality of load lock chambers 160 may be provided between the index module 120 and the transfer module 130. When a plurality of load lock chambers 160 are provided between the index module 120 and the transfer module 130, for example, when two load lock chambers 160 are provided, one load lock chamber 160 among the two load lock chambers 160 may transfer the substrate from the index module 120 to the transfer module 130, and the other load lock chamber 160 may transfer the substrate from the transfer module 130 to the index module 120. However, the present invention is not limited thereto, and the two load lock chambers 160 may perform both the transfer of the substrate from the index module 120 to the transfer module 130 and the transfer of the substrate from the transfer module 130 to the index module 120.

When the inside of the transfer module 130 is created as a vacuum environment, the load lock chamber 160 may maintain the pressure while changing the inside thereof into a vacuum environment and an atmospheric pressure environment using a gate valve or the like. The load lock chamber 160 may prevent the internal atmospheric pressure state of the transfer module 130 from being changed through this. Specifically, when a substrate is loaded or unloaded by the second transfer robot 220, the load lock chamber 160 may form the inside thereof as the same (or close to) vacuum environment as that of the transfer module 130. In addition, when a substrate is loaded or unloaded by the first transfer robot 210, the load lock chamber 160 may form the inside thereof as an atmospheric pressure environment.

Meanwhile, although not shown in FIG. 1, the semiconductor manufacturing facility 100 may further include a control module. The control module may play a role in controlling the operation of each component constituting the semiconductor manufacturing facility 100 (e.g., the first transfer robot 210 of the index module 120, the second transfer robot 220 of the transfer module 130).

The control module may be implemented by a computer or a server, including a process controller, a control program, an input module, an output module (or a display module), a memory module, and the like. In the above, the process controller may include a microprocessor for executing a control function for each component constituting the semiconductor manufacturing facility 100, and the control program may execute various treating of the semiconductor manufacturing facility 100 according to the control of the process controller. The memory module stores programs for executing various treating of the semiconductor manufacturing facility 100 according to various data and treating conditions, that is, treating recipes.

The substrate treating apparatus and the semiconductor manufacturing facility 100, which are concepts, in which the process chamber 140 and the buffer chamber 150 are integrated, have been described above with reference to FIGS. 1 to 9. The semiconductor manufacturing facility 100 may be formed in a structure having an in-line platform as described with reference to FIG. 1. In this case, the plurality of process chambers 140 may be arranged in an in-line manner with respect to the transfer module 130, and a pair of process chambers 140 may be arranged in series on both sides of each transfer module 130.

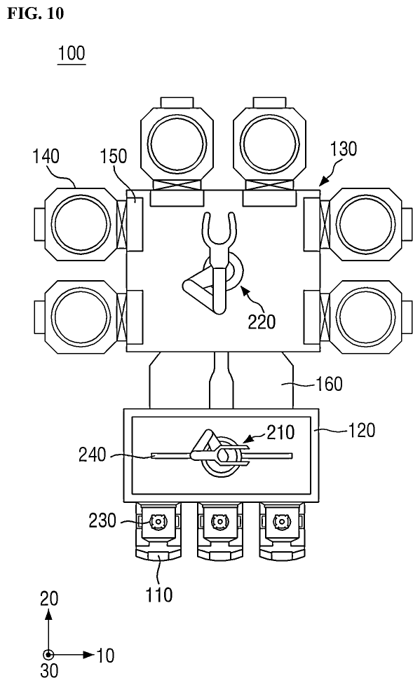

The semiconductor manufacturing facility 100 may be formed in a structure having a quad platform as shown in FIG. 10. In this case, the plurality of process chambers 140 may be arranged in a quad manner with respect to the transfer module 130. FIG. 10 is a diagram schematically illustrating an internal structure of a semiconductor manufacturing facility according to a sixth embodiment of the present invention.

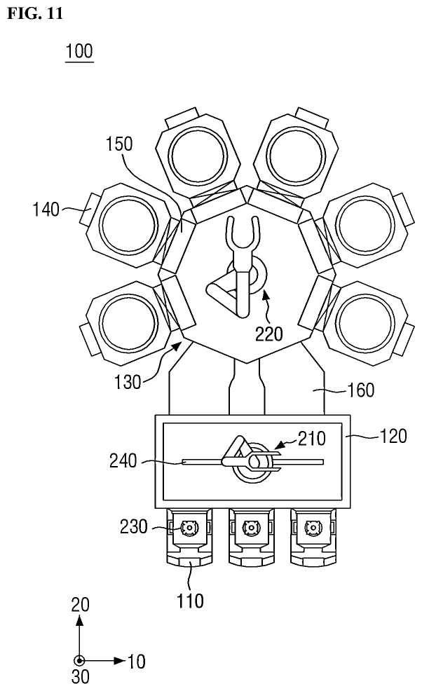

Alternatively, the semiconductor manufacturing facility 100 may be formed in a structure having a cluster platform as shown in FIG. 11. In this case, the plurality of process chambers 140 may be arranged in a cluster manner with respect to the transfer module 130. FIG. 11 is a diagram schematically illustrating an internal structure of a semiconductor manufacturing facility according to a seventh embodiment of the present invention.

The present invention relates to a method for improving UPEH (Unit Per Equipment Hour, output per unit time) for high temperature/vacuum process and improving P/C (Particle) in a track type transfer module.

UPEH improvement is required in high temperature/vacuum process, and P/C improvement is needed in Radical Clean/Etch process. In the present invention, an individual Load-Lock is configured for each process chamber (PM; Process Module) in a track-type transfer module (TM), and the Load-Lock and Robot Arm on the wafer path is maintained to a high temperature, so that UPEH and P/C can be improved.

In terms of facility configuration, the main features of the present invention are as follows.

First, a track-type TM is configured.

Second, an individual LL is configured for each PM.

Third, the LL is maintained at a high temperature.

Feature 1: Before the process, the wafer goes through the room temperature or high temperature TM arm and then is put into the high temperature LL. Thereafter, it is pre-heated in a high-temperature LL, and the time for adjusting the target process temperature can be reduced by the pre-heating.

Feature 2: After processing, it is advantageous for RDC (Radical Dry Clean) process P/C because the process finished wafer waits at high temperature LL to return to FOUP. Specifically, particles may be adsorbed on the wafer after the PM process (ex. Etching), and if the wafer waits in a high-temperature LL, it scatters due to the high-temperature condition, thereby obtaining the effect of being removed from the wafer.

Feature 3: When using two LLs, the waiting wafer waits at PM or TM Robot Arm. By using individual LLs, the wafer can always wait by at a high temperature, which is advantageous for P/C.

The effects of the present invention described above are as follows.

First, UPEH can be improved by shortening the WF (wafer) heating time.

Second, by maintaining the WF path at a high temperature, it is possible to configure an environment advantageous for RDC process P/C.

Although embodiments of the present invention have been described with reference to the above and the accompanying drawings, those skilled in the art, to which the present invention pertains, can understand that the present invention may be practiced in other specific forms without changing its technical spirit or essential features. Therefore, it should be understood that the embodiments described above are illustrative in all respects and not limiting.

What is claimed is:

1. A facility for manufacturing a semiconductor comprising:
an index module including a first transfer robot and for carrying out and transferring a substrate mounted on a container using the first transfer robot;
a transfer module including a second transfer robot and for relaying the substrate transferred by the index module using the second transfer robot;
a buffer chamber for heating the substrate relayed by the transfer module; and
a process chamber for treating the substrate heated by the buffer chamber,
wherein the buffer chamber heats the substrate while the substrate waits before being loaded into the process chamber.

2. The semiconductor manufacturing facility of claim 1, wherein the buffer chamber heats the substrate while the substrate treated by the process chamber waits before being carried out.

3. The semiconductor manufacturing facility of claim 1, wherein the buffer chamber is provided separately in each process chamber in response to the process chamber being plural.

4. The semiconductor manufacturing facility of claim 3, wherein the buffer chamber is coupled to a front surface of the process chamber, into which the substrate is loaded.

5. The semiconductor manufacturing facility of claim 1, wherein the buffer chamber provides a purge gas to the substrate while the substrate is heated.

6. The semiconductor manufacturing facility of claim 5, wherein the purge gas is a gas having a high temperature higher than room temperature.

7. The semiconductor manufacturing facility of claim 1, wherein the second transfer robot transfers the substrate heated by the buffer chamber to the process chamber,
wherein an inside of the transfer module is a vacuum environment.

8. The semiconductor manufacturing facility of claim 7, wherein a heating wire is installed in an end effector of the second transfer robot.

9. The semiconductor manufacturing facility of claim 3, wherein an inside of the transfer module is an atmospheric pressure environment.

10. The semiconductor manufacturing facility of claim 1, wherein the buffer chamber is installed inside the transfer module.

11. The semiconductor manufacturing facility of claim 10, wherein the buffer chamber is installed in a contact surface with the index module, is further installed in a surface facing the contact surface, or is installed in a section between two different process chambers in response to the process chamber being plural.

12. The semiconductor manufacturing facility of claim 11, wherein an inside of the transfer module is a vacuum environment.

13. The semiconductor manufacturing facility of claim 1, wherein the buffer chamber heats the substrate above a reference temperature,
wherein the reference temperature is a temperature, at which the substrate can be immediately treated in the process chamber.

14. The semiconductor manufacturing facility of claim 1, wherein the process chamber uses radicals to clean the substrate.

15. A facility for manufacturing a semiconductor comprising:
an index module including a first transfer robot and for carrying out and transferring a substrate mounted on a container using the first transfer robot;
a transfer module including a second transfer robot and for relaying the substrate transferred by the index module using the second transfer robot;
a buffer chamber for heating the substrate relayed by the transfer module; and
a process chamber for treating the substrate heated by the buffer chamber,
wherein the buffer chamber heats the substrate while the substrate waits before being loaded into the process chamber, and heats the substrate while the substrate treated by the process chamber waits before being carried out,
wherein, in response to the process chamber being plural, the buffer chamber is provided separately in each process chamber, and is coupled to a front surface of the process chamber, into which the substrate is loaded,
wherein the buffer chamber provides a purge gas to the substrate while the substrate is heated, and the purge gas is a gas having a high temperature higher than room temperature.

16. An apparatus for treating a substrate comprising:
a process chamber for treating a substrate; and
a buffer chamber for providing a space, in which the substrate waits,
wherein the substrate waits in the buffer chamber before being loaded into the process chamber, and waits in the buffer chamber before being carried out after being treated by the process chamber,
wherein the buffer chamber heats the substrate while the substrate waits.

17. The apparatus of claim 16, wherein the buffer chamber is provided separately in each process chamber in response to the process chamber being plural.

18. The apparatus of claim 16, wherein the buffer chamber is coupled to a front surface of the process chamber, into which the substrate is loaded.

19. The apparatus of claim 16, wherein the buffer chamber provides a purge gas to the substrate while the substrate is heated,
wherein the purge gas is a gas having a high temperature higher than room temperature.

20. The apparatus of claim 16, wherein the process chamber cleans the substrate using radicals.
